(19) United States
(12) Patent Application Publication
(10) Pub. No.: US 2026/0178797 A1
(43) Pub. Date: Jun. 25, 2026

(54) METHOD FOR TRAINING A SOLAR IRRADIANCE FORECASTING MODEL

(71) Applicant: TotalEnergies OneTech, COURBEVOIE (FR)

(72) Inventors: Amar MEDDAHI, PARIS LA DEFENSE CEDEX (FR); Arttu TUOMIRANTA, PARIS LA DEFENSE CEDEX (FR); Sébastien GUILLON, PARIS LA DEFENSE CEDEX (FR)

(73) Assignee: TotalEnergies OneTech, COURBEVOIE (FR)

(21) Appl. No.: 18/999,395

(22) Filed: Dec. 23, 2024

(51) Int. Cl. G06F 30/27

(52) U.S. Cl. CPC G06F 30/27

(57) ABSTRACT

A method for training a solar irradiance forecasting model for an area of interest, the method includes collecting a training database comprising, for each sub-period of a past period of time, solar irradiance measurements of the area of interest, determining, for each sub-period, a forecast of the solar irradiance on the basis of a baseline forecast model and of the solar irradiance measurements for said sub-period, determining, for each sub-period, an error metric, called variability, identifying the sub-periods, called more informative sub-periods, whose variability is above a predetermined variability threshold, compiling a refined training database on the basis of the solar irradiance measurements of the more informative sub-periods, and training the solar irradiance forecasting model on the basis of the refined training database.

### FIELD OF THE INVENTION

The present invention concerns a method for training a solar irradiance forecasting model for an area of interest. The invention also concerns an associated computer program product and an associated forecasting system.

### BACKGROUND OF THE INVENTION

Developing models to predict solar energy is difficult because it requires analyzing vast amounts of data. These models aim to find patterns to accurately predict solar energy output.

However, the need for large datasets and lots of computer power makes this a big challenge.

Earlier attempts to make model training better focused on improving how data is presented. There have been some new ideas to make data easier for models to use, which helps models learn faster. But research into making model training more efficient, specifically for solar energy forecasting, has been limited.

### SUMMARY OF THE INVENTION

There exists a need for a method enabling to reduce the training time of a solar irradiance forecasting model.

To this end, the invention relates to a method for training a solar irradiance forecasting model for an area of interest, the method being computer implemented and comprising the following steps:
collecting a training database, the training database comprising, for each sub-period of a past period of time, solar irradiance measurements of the area of interest,
determining, for each sub-period, a forecast of the solar irradiance on the basis of a baseline forecast model and of the solar irradiance measurements for said sub-period,
determining, for each sub-period, an error metric, called variability, on the basis of the solar irradiance measurements collected for said sub-period and the forecast determined for said sub-period,
identifying the sub-periods, called more informative sub-periods, whose variability is above a predetermined variability threshold,
compiling a refined training database on the basis of the solar irradiance measurements of the more informative sub-periods, and
training the solar irradiance forecasting model on the basis of the refined training database so as to obtain a solar irradiance forecasting model configured for predicting the solar irradiance in the area of interest at a future timestep as a function of solar irradiance measurements in the area of interest at a past timestep.

The method according to the invention may comprise one or more of the following features considered alone or in any combination that is technically possible:
the method also comprises a step of operating the solar irradiance forecasting model once trained, the operating step comprising:
   the reception of past solar irradiance measurements for the area of interest, and
   the prediction, by the solar irradiance forecasting model, of the solar irradiance in the area of interest, on the basis of the received past solar irradiance measurements for the area of interest;
the baseline forecast model is a persistent model over a defined horizon, the input of the persistent model being a solar irradiance measurement at a past timestep and the output being a prediction of the solar irradiance measurement at a future timestep equal to the past timestep plus the defined horizon, the persistent model being configured so that the prediction at the future timestep is equal to the measurement at the past timestep;
the defined horizon is inferior or equal to 10 minutes, preferably inferior or equal to 5 minutes;
the solar irradiance forecasting model is a convolutional neural network;
the training database also comprises, for each sub-period of the past period of time, sky view images of the area of interest, the refined training database being compiled on the basis of only the sky view images and solar irradiance measurements of the more informative sub-periods, the training of the solar irradiance forecasting model enabling to obtain a solar irradiance forecasting model configured for predicting the solar irradiance in the area of interest at a future timestep as a function of sky view images and associated solar irradiance measurements in the area of interest at a past timestep;
the operating step comprises:
   the reception of sky view images for the area of interest, and
   the prediction, by the solar irradiance forecasting model, of the solar irradiance in the area of interest, on the basis of the received sky view images and past solar irradiance measurements for the area of interest;
the sky view images are satellite images;
the method comprises a filtering step, the filtering step occurring between the collecting step and the step for determining a forecast for each sub-period, the filtering step comprising:
   determining the sky view images of the training database corresponding to a solar elevation angle which is below a predefined solar elevation angle, and
   filtering such sky view images and the associated solar irradiance measurements from the training database,
   the steps of the method occurring after the filtering step being carried out on the basis of the filtered training database.

The invention also relates to a computer program product comprising a computer readable medium, having thereon a computer program comprising program instructions, the computer program being loadable into a data-processing unit and causing execution of a method as previously described.

The invention also relates to a readable information carrier on which is stored a computer program product as previously described.

The invention also relates to a forecasting system for an area of interest, comprising:
an irradiance sensor suitable to measure solar irradiance in the area of interest, and
a calculator configured for implementing a method as previously described.

The forecasting system according to the invention may comprise one or more of the following features considered alone or in any combination that is technically possible:
the forecasting system also comprises an imager suitable to acquire sky view images of the area of interest, the calculator being configured for implementing a method as previously described.

### BRIEF DESCRIPTION OF THE DRAWINGS

The invention will be easier to understand in view of the following description, provided solely as an example and with reference to the appended drawings in which:

FIG. 1 is a schematic view of a forecasting system comprising an imager, an irradiance sensor and a calculator,

FIG. 2 is a schematic view of an example of the calculator of FIG. 1 interacting with a computer program product,

FIG. 3 is a flowchart of an example of implementation of a method for training a solar irradiance forecasting model for an area of interest,

FIG. 4 is a schematic representation of examples of some steps of the training method of FIG. 3, and

FIG. 5 is a graphic illustrating the forecasting model skills despite the reduction of training data.

### DETAILED DESCRIPTION

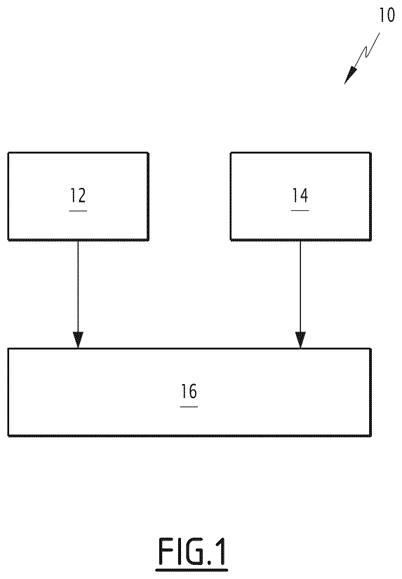

A schematic example of a forecasting system 10 is illustrated on FIG. 1.

The forecasting system 10 is configured to generate solar irradiation predictions for an area of interest. The area of interest is typically an area suitable for the installation of photovoltaic modules. The solar irradiation predictions generated by the forecasting system 10 enable for example to reduce the need for energy storage or to better predict the solar production of an installation of photovoltaic modules.

The area of interest is for example a region of space extending over several kilometers.

As illustrated on FIG. 1, the forecasting system 10 comprises an imager 12, an irradiance sensor 14 and a calculator 16.

The imager 12 is suitable to acquire images seen from the sky, called sky view images, of the area of interest.

The imager 12 comprises for example one or several cameras. The imager 12 is for example mounted on an aircraft or on a satellite. In a variant, the imager 12 is mounted on earth.

Preferably, the sky view images are satellite images.

The irradiance sensor 14 is suitable to measure solar irradiance in the area of interest.

The solar irradiance, expressed in Watt per square meter (W/m²), is the incident radiant flux (power) received by a surface per unit area.

The irradiance sensor 14 comprises for example one or several pyranometers.

The calculator 16 is configured for implementing a method for training a solar irradiance forecasting model for the area of interest, that will be described later on.

The solar irradiance forecasting model is typically a deep learning model. Typically, the solar irradiance forecasting model is a neural network, such as a convolutional neural network. However, the method is adapted to train others types of forecasting models.

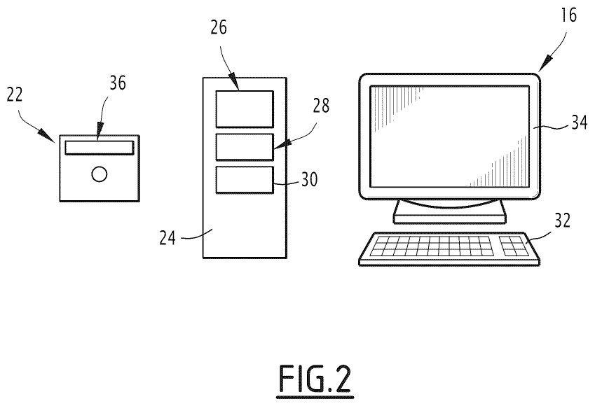

In an example, as illustrated on FIG. 2, the calculator 16 interacts with a computer program product 22.

The calculator 16 is preferably a computer.

More generally, the calculator 16 is a computer or computing system, or similar electronic computing device adapted to manipulate and/or transform data represented as physical, such as electronic, quantities within the computing system's registers and/or memories into other data similarly represented as physical quantities within the computing system's memories, registers or other such information storage, transmission or display devices.

As illustrated on FIG. 2, the calculator 16 comprises a processor 24 comprising a data processing unit 26, memories 28 and a reader 30 for information media. In the example illustrated on FIG. 2, the calculator 16 comprises a human machine interface 32, such as a keyboard, and a display 34.

The computer program product 22 comprises an information medium 36.

The information medium 36 is a medium readable by the calculator 16, usually by the data processing unit 26. The readable information medium 36 is a medium suitable for storing electronic instructions and capable of being coupled to a computer system bus.

By way of example, the information medium 36 is a USB key, a floppy disk or flexible disk (of the English name “Floppy disc”), an optical disk, a CD-ROM, a magneto-optical disk, a ROM memory, a memory RAM, EPROM memory, EEPROM memory, magnetic card or optical card.

On the information medium 36 is stored the computer program 22 comprising program instructions.

The computer program 22 is loadable on the data processing unit 26 and is adapted to entail the implementation of a method for training a solar irradiance forecasting model for an area of interest, when the computer program 22 is loaded on the processing unit 26 of the calculator 16.

In a variant, the computer program is stored on a cloud accessible through a server.

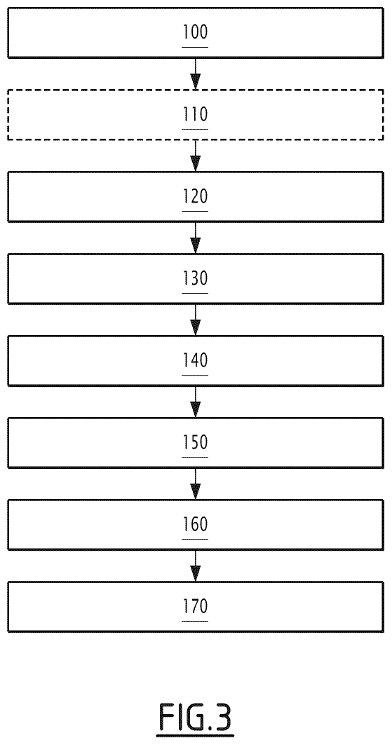

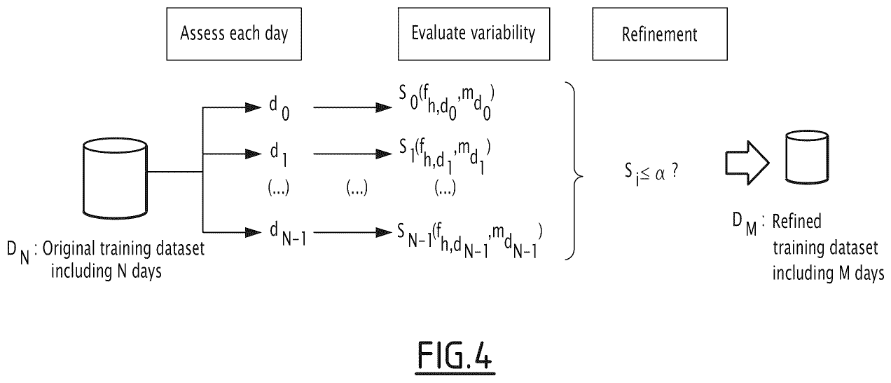

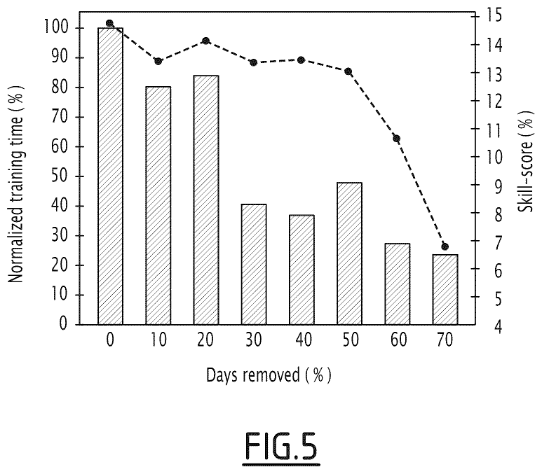

Operation of the calculator 16 will now be described with reference to FIG. 3, which diagrammatically illustrates an example of implementation of a method for training a solar irradiance forecasting model for an area of interest, and to FIGS. 4 and 5 which illustrate in more detail some steps or advantages of this method.

The steps of the training method which are described in what follows are typically implemented by the calculator 16 in interaction with the computer program product 22, that is to say is implemented by a computer.

The training method comprises a step 100 of collecting a training database.

The training database comprises, for each day of a past period of time, sky view images of the area of interest and associated solar irradiance measurements of the area of interest.

The sky view images have typically been acquired by the imager 12. The solar irradiance measurements have for example been taken by an irradiance sensor 14.

In the description, we use the term “day”, however the person skilled in the art will understand that the term day could be replace by any other sub-period of time, such as hours, several days, or months.

The data of the training database corresponds to a succession of days extending for example over at least a year.

Optionally, the training method comprises a step 110 of filtering the training database.

The filtering step 110 comprises:
determining the sky view images of the training database corresponding to a solar elevation angle which is below a predefined solar elevation angle, and
filtering such sky view images and the associated solar irradiance measurements from the training database.

The predefined solar elevation angle is for example chosen at 10 degrees, preferably at 15 degrees.

The steps of the method occurring after the filtering step are then carried out on the basis of the filtered training database.

The training method comprises a step 120 of determining, for each day, a forecast of the solar irradiance.

The forecast is performed on the basis of a baseline forecast model and of the solar irradiance measurements of each day. The baseline forecast model is a simple model suitable for predicting solar irradiance.

In an example, the baseline forecast model is a persistent model over a defined horizon. The input of the persistent model is a solar irradiance measurement at a past timestep and the output is a prediction of the solar irradiance measurement at a future timestep equal to the past timestep plus the defined horizon. The persistent model is configured so that the prediction at the future timestep is equal to the measurement at the past timestep. In practice, the persistent model is applied to clear-sky index i.e., solar irradiance divided by its clear-sky counterpart. The clear sky counterpart is the solar irradiance where the impact of clouds is removed. Then, the predicted clear-sky indexes are converted again into solar irradiance.

The defined horizon is for example inferior or equal to 10 minutes, preferably inferior or equal to 5 minutes.

Other embodiments are nonetheless possible.

The training method comprises a step 130 of determining, for each day, an error metric, called variability, on the basis of the solar irradiance measurements collected for said day and the forecast determined for said day.

Preferably, the variability for each day is the difference between the solar irradiance measurements collected for said day, normalized by the corresponding solar irradiance measurements without clouds, and the solar irradiance forecasted determined for said day, normalized by the corresponding solar irradiance forecasted without clouds.

In a variant, the variability for each day is the difference between the solar irradiance measurements collected for said day and the forecast determined for said day.

In another example, the error metric is the mean absolute error (MAE). Other embodiments are nonetheless possible.

The training method comprises a step 140 of identifying the days, called more informative days, whose variability is above a predetermined variability threshold.

The predetermined variability threshold is chosen so as to keep only the days whose data are the more challenging and representative of diverse solar conditions, that is to say the days having a variability above the predetermined variability threshold.

For example, each day having a variability (forecast error) below the predetermined variability threshold is marked as less informative. The other days are the more informative days.

The training method comprises a step 150 of compiling a refined training database on the basis of only the sky view images and solar irradiance measurements of the more informative days. This enables to keep only the days that are sufficiently variable and informative.

In particular, FIG. 4 illustrates an original training database comprising data corresponding to N days. As described in steps 120, 130 and 140, each day of the original training database is assessed individually. In particular, a variability is evaluated for each day (step 130). On this figure, the variability for each day is described with the following formula:

$${S}_{i} = ( {f}_{h , {d}_{i}} , {m}_{{d}_{i}} )$$

where:
   i is comprised between 0 and N−1, N being the number of days of the original training database,
   Sᵢ is the variability for the day i (for example the MAE),
   f is the baseline forecast model,
   h is the defined horizon (for the persistence model), and
   m is the observed data (measurements) for the day i.

As illustrated on FIG. 4, the variability determined for each day is compared to a predetermined variability threshold a. Only, the data of the days whose variability threshold is above the predetermined variability threshold are compiled to form the refined training database. The refined training database thus comprises data corresponding to M days, M being strictly inferior to N.

The training method comprises a step 160 of training the solar irradiance forecasting model on the basis of the refined training database. This enables to obtain a solar irradiance forecasting model configured for predicting the solar irradiance in the area of interest at a future timestep as a function of sky view images and associated solar irradiance measurements in the area of interest at a past timestep.

The solar irradiance forecasting model has thus be trained for a specific area of interest. The solar irradiance forecasting model could then be trained again to address another area of interest.

The solar irradiance forecasting model is typically trained according to a training technique. The training technique implements, for example, a supervised learning. The training technique makes it possible to configure the solar irradiance forecasting model as the solar irradiance forecasting model is trained on the basis of the refined training database.

The training technique is for example an ADAM optimization technique. However, other optimization methods, such as variants of Gradient Descent (e.g., Stochastic Gradient Descent, SGD) or adaptive gradient approaches like RMSProp, can also be employed.

In an example, the training method also comprises a step 170 of operating the solar irradiance forecasting model once trained. The operating step 170 comprises:
the reception of sky view images and past solar irradiance measurements for the area of interest, and
the prediction, by the solar irradiance forecasting model, of the solar irradiance in the area of interest, on the basis of the received sky view images and past solar irradiance measurements for the area of interest.

The obtained solar irradiation predictions are then for example used to reduce the need for energy storage or to better predict the solar production of an installation of photovoltaic modules.

### Experimental Data

### The Dataset

To validate this training method, we utilized a dataset spanning from 2019 to 2023, collected in La Tour-de-Salvagny, France. It comprises minute-by-minute synchronized sky view images and Global Horizontal Irradiance (GHI) readings.

Established preprocessing techniques were applied. Notably, samples with solar elevation angles below 15 degrees were filtered out to mitigate the challenges associated with low solar elevations, such as increased measurement uncertainty and inaccuracies in clear-sky models, especially during sunrise and sunset periods. These conditions can adversely affect error metrics, compromising forecast reliability. Furthermore, at low solar elevations, the sun's proximity to the lens edge in images complicates cloud extrapolation, and the diminished photovoltaic (PV) production during these periods reduces the necessity for precise forecasting, a persistence method can be used instead. The dataset normalization for GHI was conducted using McClear model to calculate the Clear Sky Index (CSI), while sky view images underwent preprocessing, including size reduction, cropping, and distortion correction, to accurately depict sky conditions. The use of the McClear model is for example described in the article Mireille Lefevre et al. “McClear: a new model estimating downwelling solar radiation at ground level in clear-sky conditions”. In: Atmospheric Measurement Techniques (2013).

### Forecasting Model

The forecasting model developed in this study is a deep learning framework that integrates temporal irradiance data with sequential sky view images to predict future GHI levels. This multi-modal neural network is designed to analyze and correlate spatio-temporal data, enhancing the accuracy of solar irradiance forecasts.

### Model Training

Training of the forecasting model was directed towards minimizing the MAE for a forecast lead-time of five minutes, employing the ADAM optimization algorithm for weight adjustment. A portion of the initial dataset, spanning four years, was set aside for model development and testing, specifically a 7-month period for hyperparameter tuning and an 8-month period for final evaluation, both excluded from the training set to guarantee testing on unseen data. The remainder of the dataset was utilized for model optimization. The training duration, defined by the time taken for the model to achieve convergence, was determined by the cessation of performance improvements on the development set. This approach facilitates a fair comparison of model performance across different configurations, ensuring that each model is evaluated at its peak efficiency within the context of our skill-driven training methodology.

### Model Validation

The deep learning model was evaluated against established benchmarks and various commercial forecasting solutions, which employ distinct sky imager technologies, including Visible and Infrared (IR) modalities. These commercial solutions underwent testing during different intervals within the preliminary testing phase, yielding two separate sets of comparisons (Testing Set A and Testing Set B). As detailed in Table 1, our model consistently outperformed both the commercial forecasting solutions and the persistence baseline based on the normalized GHI across all metrics.

| | Testing Set A (3 months) | | | Testing Set B (5 months) | | |
|---|---|---|---|---|---|---|
| | RMSE | nRMSE | Skill- | | | Skill- |
| Metric | [W · m⁻²] | [%] | Score [%] | RMSE | nRMSE | Score |
| Commercial (visible) | 141.19 | 36.14 | −16.90 | N/A | N/A | N/A |
| Commercial (IR) | N/A | N/A | N/A | 88.78 | 35.59 | −6.80 |
| Ours | 77.09 | 23.22 | 15.05 | 34.74 | 25.28 | 16.15 |

### Skill-Driven Assessment

Our empirical analysis, underpinned by the skill-driven framework, included eight distinctive experiments, each replicated three times. Models were selected based on optimal RMSE performance at varying thresholds of excluded days. The evaluation emphasized Normalized Training Time and RMSE Forecast Skill, benchmarked against a persistence model based on normalized GHI.

As depicted in FIG. 5, a correlation is apparent between the percentage of days removed and the training efficiency. In particular, on FIG. 5, normalized training time is depicted by the bars, and the dashed line indicates the RMSE Forecast Skill. This relationship demonstrates the model's consistent forecasting skill despite the reduction of training data. More specifically, results indicate that models trained on datasets reduced by up to 50% preserve competitive accuracy, corroborating the effectiveness of our skill-driven data selection methodology. Concurrently, training time was curtailed by as much as 50%, indicating efficiency gains. A notable finding is the inflection point beyond which further data reduction ceases to contribute to efficiency gains, as indicated by the diminishing Skill-Score. The performance decline observed in the experiments can be attributed to several factors. Predominantly, when the model's capacity becomes disproportionately large relative to the amount of available data, underfitting may occur. Regarding the training time, this variable is influenced by multiple factors, of which dataset size is one but not the sole determinant. This explains the incremental decrease observed.

Hence, the training method enables to optimize the training dataset for deep learning applications in solar forecasting. In particular, by selectively keeping samples in a database based on their informative value, represented by the variability in solar irradiance, the method ensures that the training database is both highly relevant and challenging for the model. This selective inclusion is achieved through an algorithm that evaluates each day's solar variability using an error metric, such as the Mean Absolute Error (MAE) from 5-minute persistence forecasts (naive forecasting model). Days exhibiting minimal variability, which are less likely to contribute to model improvement, are then excluded from the training database.

The refinement of the dataset is central to our training approach, focusing on a condensed yet informative subset of data. This strategy is based on the principle that data quality significantly affects model performance in deep learning. By targeting data that presents substantial forecasting challenges, our method seeks to improve the training efficiency and effectiveness of models for solar irradiance forecasting, thereby reducing the need for repetitive and less informative samples.

The method enables therefore to train a solar irradiance forecasting model with a smaller set of data (up to 50% less data) and training time, without losing accuracy.

The person skilled in the art will understand that the embodiments and variants described above can be combined to form new embodiments provided that they are technically compatible.

In addition, it should be noted that “days” have been given as examples of timeframe for the different steps of the method. However, the method works for any other sub-periods of time, such as for example hours, days, or months, or any other timeframe longer than the acquisition interval and shorter than the total timeframe of the database. Hence, the term day could be replace by sub-period in all the description.

Moreover, it should also be noted that the method works without taking into account sky view images in the method. In this case, training database and refined training database are only composed of solar irradiance measurements of the area of interest. In this variant, the imager 12 is optional in the forecasting system because sky view images are not needed. Hence, the term sky view images could be suppress in all the description (except the experimental data). However, the use of sky view images enable to get some more information and to be more precise in the forecasting.

1. A method for training a solar irradiance forecasting model for an area of interest, the method being computer implemented and comprising the following steps:
collecting a training database, the training database comprising, for each sub-period of a past period of time, solar irradiance measurements of the area of interest,
determining, for each sub-period, a forecast of the solar irradiance on the basis of a baseline forecast model and of the solar irradiance measurements for said sub-period,
determining, for each sub-period, an error metric, called variability, on the basis of the solar irradiance measurements collected for said sub-period and the forecast determined for said sub-period,
identifying the sub-periods, called more informative sub-periods, whose variability is above a predetermined variability threshold,
compiling a refined training database on the basis of the solar irradiance measurements of the more informative sub-periods, and
training the solar irradiance forecasting model on the basis of the refined training database so as to obtain a solar irradiance forecasting model configured for predicting the solar irradiance in the area of interest at a future timestep as a function of solar irradiance measurements in the area of interest at a past timestep.

2. The method according to claim 1, wherein the method also comprises a step of operating the solar irradiance forecasting model once trained, the operating step comprising:
the reception of past solar irradiance measurements for the area of interest, and
the prediction, by the solar irradiance forecasting model, of the solar irradiance in the area of interest, on the basis of the received past solar irradiance measurements for the area of interest.

3. The method according to claim 1, wherein the baseline forecast model is a persistent model over a defined horizon, the input of the persistent model being a solar irradiance measurement at a past timestep and the output being a prediction of the solar irradiance measurement at a future timestep equal to the past timestep plus the defined horizon, the persistent model being configured so that the prediction at the future timestep is equal to the measurement at the past timestep.

4. The method according to claim 3, wherein the defined horizon is inferior or equal to 10 minutes.

5. The method according to claim 3, wherein the defined horizon is inferior or equal to 5 minutes.

6. The method according to claim 1, wherein the solar irradiance forecasting model is a convolutional neural network.

7. The method according to claim 1, wherein the training database also comprises, for each sub-period of the past period of time, sky view images of the area of interest, the refined training database being compiled on the basis of only the sky view images and solar irradiance measurements of the more informative sub-periods, the training of the solar irradiance forecasting model enabling to obtain a solar irradiance forecasting model configured for predicting the solar irradiance in the area of interest at a future timestep as a function of sky view images and associated solar irradiance measurements in the area of interest at a past timestep.

8. The method according to claim 2, wherein the operating step comprises:
the reception of sky view images for the area of interest, and
the prediction, by the solar irradiance forecasting model, of the solar irradiance in the area of interest, on the basis of the received sky view images and past solar irradiance measurements for the area of interest.

9. The method according to claim 7, wherein the sky view images are satellite images.

10. The method according to claim 7, wherein the method comprises a filtering step, the filtering step occurring between the collecting step and the step for determining a forecast for each sub-period, the filtering step comprising:
determining the sky view images of the training database corresponding to a solar elevation angle which is below a predefined solar elevation angle, and
filtering such sky view images and the associated solar irradiance measurements from the training database,
the steps of the method occurring after the filtering step being carried out on the basis of the filtered training database.

11. The readable information carrier on which a computer program is stored, the computer program comprising program instructions, the computer program being loadable into a data-processing unit and causing execution of a method according to claim 1 when the computer program is run by the data-processing unit.

12. A forecasting system for an area of interest, comprising:
an irradiance sensor suitable to measure solar irradiance in the area of interest, and
a calculator configured for implementing a method according to claim 1.

13. A forecasting system, comprising an irradiance sensor suitable to measure solar irradiance in the area of interest, and a calculator wherein the forecasting system also comprises an imager suitable to acquire sky view images of the area of interest, the calculator being configured for implementing a method according to claim 7.
